(19) United States
(12) Patent Application Publication
(10) Pub. No.: US 2025/0006604 A1
(43) Pub. Date: Jan. 2, 2025

(54) SEMICONDUCTOR DEVICE

(71) Applicant: DENSO CORPORATION, Kariya-city (JP)

(72) Inventor: Kazuki YAMAUCHI, Kariya-city (JP)

(21) Appl. No.: 18/882,346

(22) Filed: Sep. 11, 2024

Related U.S. Application Data
(63) Continuation of application No. PCT/JP2023/005316, filed on Feb. 15, 2023.

(30) Foreign Application Priority Data
Mar. 15, 2022 (JP) 2022-040283

(51) Int. Cl. H01L 23/495; H01L 23/00; H01L 23/31; H01L 25/065

(52) U.S. Cl. CPC H01L 23/49575; H01L 23/49541; H01L 24/48; H01L 25/0655; H01L 23/3107; H01L 2224/48137; H01L 2224/48175; H01L 2225/065

(57) ABSTRACT

A semiconductor device includes: a package; a first island; a first semiconductor chip mounted on the first island; a second island; a second semiconductor chip mounted on the second island; and an insulating element provided on one or both of the first semiconductor chip and the second semiconductor chip. Each of the first island and the second island has an extension portion extending to be exposed from the package, and is supported by the package through the extension portion.

### CROSS REFERENCE TO RELATED APPLICATION

The present application is a continuation application of International Patent Application No. PCT/JP2023/005316 filed on Feb. 15, 2023, which designated the U.S. and claims the benefit of priority from Japanese Patent Application No. 2022-040283 filed on Mar. 15, 2022. The entire disclosures of all of the above applications are incorporated herein by reference.

### TECHNICAL FIELD

The present disclosure relates to a semiconductor device including a package having a first side and a second side opposing to each other in a plan view, and terminals arranged along each of the first side and the second side.

### BACKGROUND

In a semiconductor device, semiconductor chips are insulated from each other in one package, which may be referred to as an insulating PKG. A small outline package (SOP) is one of the insulating PKGs, in which the creepage distance between the opposing outer leads is designed by taking into consideration the chip size and the like.

### SUMMARY

In one aspect of the present disclosure, a semiconductor device includes: a package having a first side, a second side, a third side and a fourth side in a plan view; a plurality of terminals arranged along each of a first side and a second side of the package opposing to each other; a first island having four sides in a plan view, one of the four sides of the first island opposing the first side of the package; a second island, separated from the first island, having four sides in a plan view, one of the four sides of the second island opposing the second side of the package; at least one first semiconductor chip mounted on the first island; at least one second semiconductor chip mounted on the second island; an insulating element provided on one or both of the first semiconductor chip and the second semiconductor chip; a first wire electrically connecting the first semiconductor chip to the terminals arranged on the first side; a second wire electrically connecting the second semiconductor chip to the terminals arranged on the second side; and a third wire electrically connecting the first semiconductor chip and the second semiconductor chip. One of the first island and the second island has an extension portion extending to be exposed from one of the third side and the fourth side of the package, and is supported by the package through the extension portion.

### BRIEF DESCRIPTION OF DRAWINGS

The features and advantages of the present disclosure will become more apparent from the following detailed description made with reference to the accompanying drawings. In the drawings:

FIG. 1 is a perspective view schematically illustrating a semiconductor device according to a first embodiment;

FIG. 2 is a plan view illustrating a schematic configuration of the semiconductor device according to the first embodiment, with a package seen through;

FIG. 3 is a plan view illustrating a schematic configuration of the semiconductor device according to the first embodiment, in which some components are omitted;

FIG. 4 is a schematic sectional view illustrating the semiconductor device according to the first embodiment;

FIG. 5 is a plan view illustrating a schematic configuration of the semiconductor device according to the first embodiment, with a package seen through;

FIG. 6 is a diagram illustrating a schematic configuration of a circuit mounted on the semiconductor device according to the first embodiment;

FIG. 7 is a perspective view illustrating a semiconductor device of a first comparative example;

FIG. 8 is a plan view illustrating the semiconductor device of the first comparative example, in which some components are omitted;

FIG. 9 is a schematic sectional view illustrating a semiconductor device of a second comparative example;

FIG. 10 is a plan view illustrating a schematic configuration of the semiconductor device of the second comparative example, with a package seen through;

FIG. 11 is a plan view illustrating a schematic configuration of a semiconductor device according to a first modification of the first embodiment, in which some components are omitted;

FIG. 12 is a plan view illustrating a schematic configuration of a semiconductor device according to a second modification of the first embodiment, in which some components are omitted;

FIG. 13 is a plan view illustrating a schematic configuration of a semiconductor device according to a third modification of the first embodiment, in which some components are omitted;

FIG. 14 is a plan view illustrating a schematic configuration of a semiconductor device according to a fourth modification of the first embodiment, in which some components are omitted;

FIG. 15 is a plan view illustrating a schematic configuration of a semiconductor device according to a fifth modification of the first embodiment, with a package seen through;

FIG. 16 is a plan view illustrating a schematic configuration of a semiconductor device according to a sixth modification of the first embodiment, with a package seen through;

FIG. 17 is a plan view illustrating a schematic configuration of a semiconductor device according to a seventh modification of the first embodiment, with a package seen through;

FIG. 18 is a plan view illustrating a schematic configuration of a semiconductor device according to an eighth modification of the first embodiment, with a package seen through; and

FIG. 19 is a plan view illustrating a schematic configuration of a semiconductor device according to a second embodiment, with a package seen through.

### DETAILED DESCRIPTION

A semiconductor device has a function of insulating semiconductor chips from each other in one package. Hereinafter, such a configuration may be referred to as an insulating PKG. There is a small outline package (SOP) as the insulating PKG. In the SOP, the distance between two opposing outer leads is designed by considering the chip size of the semiconductor chip to be mounted, the comparative tracking index (CTI) value of resin forming the package, and the like.

Specifically, the chip size determines a minimum distance that is the lower limit of the distance to be ensured between the outer leads, and the CTI value determines a specified distance to be ensured between the outer leads for insulation. The insulating PKG is designed so that the creepage distance between the outer leads is the greater of the minimum distance and the specified distance.

In order to ensure such a creepage distance in the SOP, it is typical to adopt a structure, in which an island is suspended by two outer leads at both ends, while plural outer leads are arranged, for supporting the island, on which a semiconductor chip is mounted, in the package. In the following, such a structure may be referred to as a typical suspension structure.

In a typical suspension structure, the outer leads at the both ends are fixed to the same ground potential as the island, so that functional pins cannot be assigned to the outer leads at the both ends. Therefore, in the case of a typical suspension structure, it is difficult to reduce the package size in order to ensure the desired number of functional pins.

In response to this, a suspension lead may be disposed between the outer lead at the end and another outer lead located on the inner side, and the island is suspended by the suspension lead. In the following, such a structure may be referred to as a suspension structure. With such a suspension structure, it is possible to assign functional pins to the outer leads at the both ends. However, the additional suspension lead makes it difficult to shorten the lead pitch, resulting in that it becomes difficult to reduce the package size.

The present disclosure provides a semiconductor device to increase the number of terminals to be assigned as functional pins while keeping the package size small.

In one aspect of the present disclosure, a semiconductor device includes a package having four sides in a plan view, and terminals arranged on a first side and a second side of the four sides opposite to each other. The semiconductor device further includes a first island, a second island, at least one first semiconductor chip mounted on the first island, at least one second semiconductor chip mounted on the second island, an insulating element, a first wire, a second wire and a third wire.

The first island has four sides in a plan view, and one of the four sides opposes the first side of the package. The second island is separated from the first island and has four sides in a plan view, one of the four sides being positioned to oppose the second side of the package. The insulating element is provided on one or both of the first semiconductor chip and the second semiconductor chip. The first wire electrically connects the first semiconductor chip to the terminals arranged on the first side. The second wire electrically connects the second semiconductor chip to the terminals arranged on the second side. The third wire electrically connects the first semiconductor chip and the second semiconductor chip.

In the above configuration, one or both of the first island and the second island has an extension portion extending to be exposed from one or both of a third side and a fourth side of the four sides of the package, and is supported by the package through the extension portion. With this configuration, of the multiple terminals arranged on each of the first and second sides, at least one of the terminals arranged at both ends no longer needs to be used to suspend the island, and can therefore be assigned as a functional pin.

In this case, the extension portion is exposed from one or both of the third side and the fourth side, which are different from the first side and the second side on which the terminals are arranged, of the four sides of the package. Therefore, with the above configuration, the lead pitch, i.e., the distance between the terminals, does not become long as in a suspension structure. As a result, the package size can be kept small. Therefore, according to the above configuration, it is possible to increase the number of terminals to be assigned as functional pins while keeping the package size small.

The following will describe embodiments of the present disclosure with reference to the accompanying drawings. In each embodiment, the substantially same components are denoted by the same reference numerals and description thereof will be omitted.

### First Embodiment

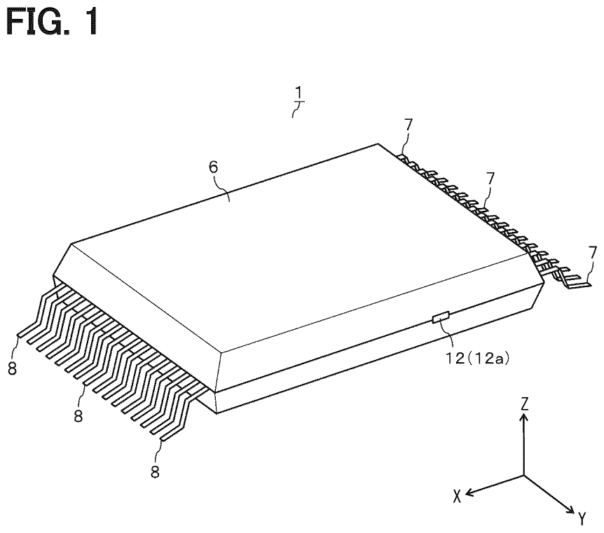

Hereinbelow, a first embodiment will be described with reference to FIGS. 1 to 18.

As shown in FIGS. 1 to 3, a semiconductor device 1 according to the present embodiment is mounted on a vehicle such as an automobile, and is configured as an integrated circuit (IC) in an insulating PKG such as SOP. The semiconductor device 1 includes a first island 2, a second island 3, a semiconductor chip 4, a semiconductor chip 5, and a package 6 made of a molded resin to seal them.

In this specification, the thickness direction of the semiconductor chip 4, 5 is the Z direction or the up-down direction. A direction perpendicular to the Z direction, specifically the arrangement direction of the semiconductor chips 4 and 5, is defined as the X direction. A direction perpendicular to both the Z direction and the X direction is defined as the Y direction. In this specification, a plan view refers to a state viewed in the Z direction. In other words, in this specification, a shape in a plan view means a shape along an XY plane defined by the X direction and the Y direction.

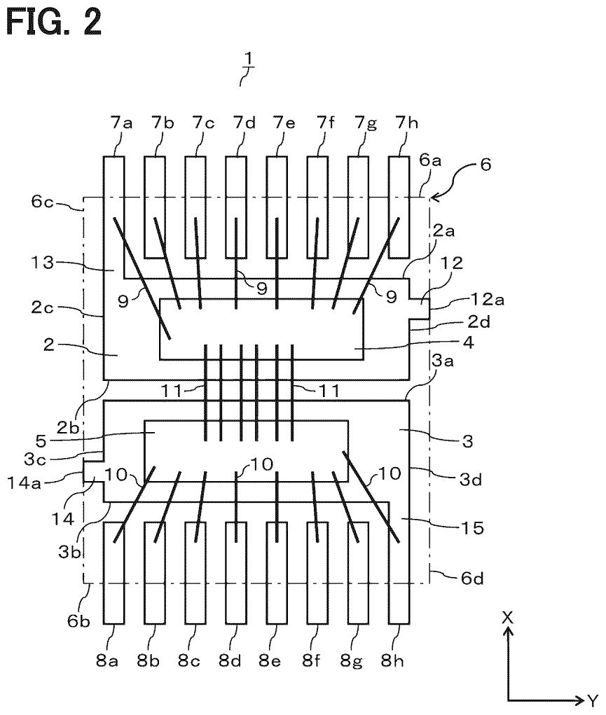

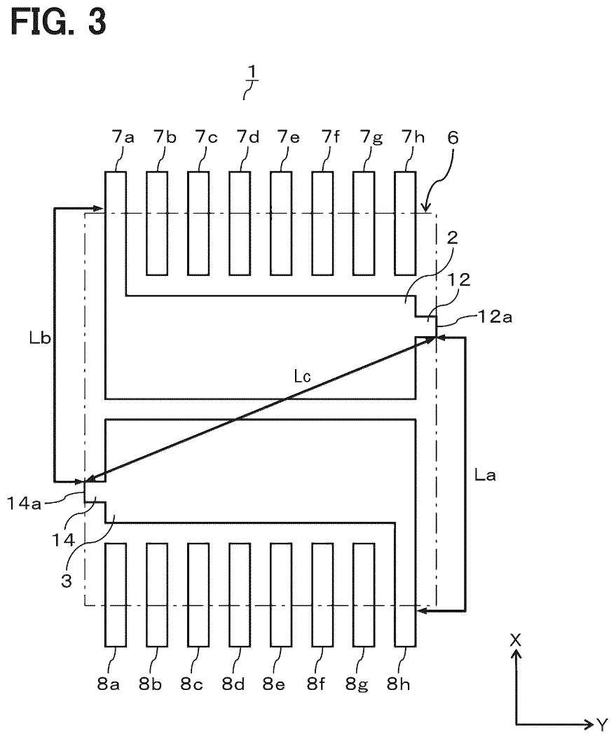

As shown in FIGS. 2 and 3, the semiconductor device 1 includes the package 6 having four sides 6a, 6b, 6c, 6d in a plan view, as a housing. Of the four sides 6a to 6d, the two opposing sides 6a, 6b will be referred to as the first side 6a and the second side 6b, respectively. The other two sides 6c and 6d other than the first side 6a and the second side 6b, among the four sides 6a to 6d, will be referred to as the third side 6c and the fourth side 6d, respectively.

Plural leads 7 are arranged along the first side 6a, and plural leads 8 are arranged along the second side 6b. The number of the leads 7, 8 is actually “16”, but for ease of understanding, FIG. 2 and the like show only a smaller number of leads 7, 8 than the actual number. Specifically, in FIGS. 2 and 3, only eight leads 7, 8 are shown. In this case, in order to distinguish between the eight leads 7, 8, alphabets are added to the end of the reference numerals. However, when there is no need to distinguish between them, the alphabet at the end will be omitted and they will be referred to collectively as the lead 7, 8.

In the semiconductor device 1, an island is divided into two islands 2 and 3 within the package 6. The islands 2 and 3 will be referred to as the first island 2 and the second island 3. The first island 2 and the second island 3 are both made of metal such as copper, iron, or an alloy thereof, and have a plate shape. The first island 2 has a shape having four sides 2a, 2b, 2c, 2d in a plan view. In this specification, the term “side” is not limited to a line segment, but also includes a curved portion. The shape of the first island 2 in a plan view is actually a complex shape that is not a simple rectangle, but for ease of explanation, in FIG. 2 and other figures, the shape of the first island 2 in a plan view is shown as a simple rectangle.

The second island 3 is separated from the first island 2 and has four sides 3a, 3b, 3c, 3d in a plan view. The shape of the second island 3 in a plan view is actually a complex shape that is not a simple rectangle, but for ease of explanation, in FIG. 2 and other figures, the shape of the second island 3 in a plan view is shown as a simple rectangle.

The first island 2 is disposed in the package 6 such that one side 2a of the four sides 2a to 2d opposes the first side 6a of the package 6. The second island 3 is disposed in the package 6 such that one side 3b of the four sides 3a to 3d opposes the second side 6b of the package 6. The first island 2 and the second island 3 are arranged in the package 6 such that the side 2b of the first island 2 and the side 3a of the second island 3 are located adjacent to each other.

One semiconductor chip 4 is mounted on the first island 2. One semiconductor chip 5 is mounted on the second island 3. The semiconductor chips 4 and 5 are referred to as the first semiconductor chip 4 and the second semiconductor chip 5, respectively. The first semiconductor chip 4 and the second semiconductor chip 5 are both made of a semiconductor such as silicon and have a rectangular plate shape. One or both of the first semiconductor chip 4 and the second semiconductor chip 5 has an insulating element for insulating between the circuits mounted on the first semiconductor chip 4 and the second semiconductor chip 5.

The lead 7, 8, like the first island 2 and the second island 3, is made of a metal such as copper or iron. The multiple leads 7 and the first semiconductor chip 4 are wired and electrically connected via multiple wires 9. The multiple leads 8 and the second semiconductor chip 5 are wired and electrically connected via multiple wires 10. The first semiconductor chip 4 and the second semiconductor chip 5 are wired and electrically connected via multiple wires 11. The wire 9, 10 is formed by usual wire bonding and is made of gold, silver, copper, aluminum, or the like. In FIG. 2 and other figures, only some of the wires 9 to 11 are indicated by reference numerals.

The wire 9 is an example of first wire that electrically connects the first semiconductor chip 4 and the lead 7 arranged on the first side 6a. The wire 10 is an example of second wire that electrically connects the second semiconductor chip 5 and the lead 8 arranged on the second side 6b. The wire 11 is an example of third wire that electrically connects the first semiconductor chip 4 and the second semiconductor chip 5. The inner lead, which is a connection portion of the lead 7, 8 with the wire 9, 10, is sealed with the molding resin that constitutes the package 6. The outer lead, which is a portion of the lead 7, 8 opposite to the connection portion connected to the wire 9, 10, is exposed from the molding resin and adapted to be connected to an external wiring member or the like.

The first island 2 includes an extension portion 12 and a terminal connector 13. The extension portion 12 extends to be exposed trom the fourth side 6d, which is one of the third side 6c and the fourth side 6d, and is formed integrally with the first island 2. In this case, the extension portion 12 will also be referred to as a first extension portion 12. The first extension portion 12 extends from the side 2d of the first island 2 at a position on the side 2d between the center in the X direction and the leads 7 arranged on the first side 6a of the package 6, and is exposed from the fourth side 6d.

The terminal connector 13 is connected to the lead 7a located at the farthest position from the first extension portion 12, of the multiple leads 7 arranged on the first side 6a of the package 6, and is formed integrally with the first island 2. In this case, the terminal connector 13 will be referred to as a first terminal connector 13. The first island 2 is supported by the package 6 through the first extension portion 12 and the first terminal connector 13.

The second island 3 includes an extension portion 14 and a terminal connector 15. The extension portion 14 extends to be exposed from the third side 6c, which is different from the one of the third side 6c and the fourth side 6d, and is formed integrally with the second island 3. The extension portion 14 will be referred to as the second extension portion 14. The second extension portion 14 extends from the side 3c of the second island 3 so as to be exposed from the third side 6c, at a position between the center in the X direction and the leads 8 arranged on the second side 6b of the package 6.

The terminal connector 15 is connected to the lead 8h located at the farthest position from the second extension portion 14, among the multiple leads 8 arranged on the second side 6b of the package 6, and is formed integrally with the second island 3. The terminal connector 15 will be referred to as the second terminal connector 15. The second island 3 is supported by the package 6 through the second extension portion 14 and the second terminal connector 15.

A part of the first extension portion 12 exposed to the outside of the package 6 is a first exposed portion 12a. In other words, the first exposed portion 12a is to be electrically connected to the first island 2. A part of the second extension portion 14 exposed to the outside of the package 6 is a second exposed portion 14a. In other words, the second exposed portion 14a is to be electrically connected to the second island 3. In the semiconductor device 1, the first exposed portion 12a is insulated from the outer lead of the lead 8, and the second exposed portion 14a is insulated from the outer lead of the lead 7. The first exposed portion 12a is insulated from the second exposed portion 14a.

As shown in FIG. 3, in the semiconductor device 1, the creepage distances are defined at the above-mentioned insulating points, and equal to or greater than a specified distance. Specifically, the creepage distance La is defined between the first exposed portion 12a and the outer lead of the lead 8. The creepage distance Lb is defined between the second exposed portion 14a and the outer lead of the lead 7. The creepage distance Lc is defined between the first exposed portion 12a and the second exposed portion 14a. The specified distance is related to insulation that has been determined in advance, and corresponds to the minimum creepage distance that is specified based on the operating voltage of the circuit, the CTI value of the resin that constitutes the package 6, and the like.

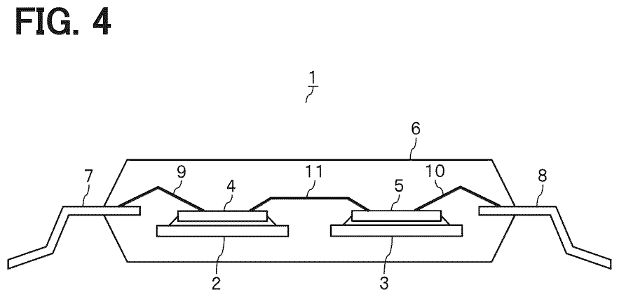

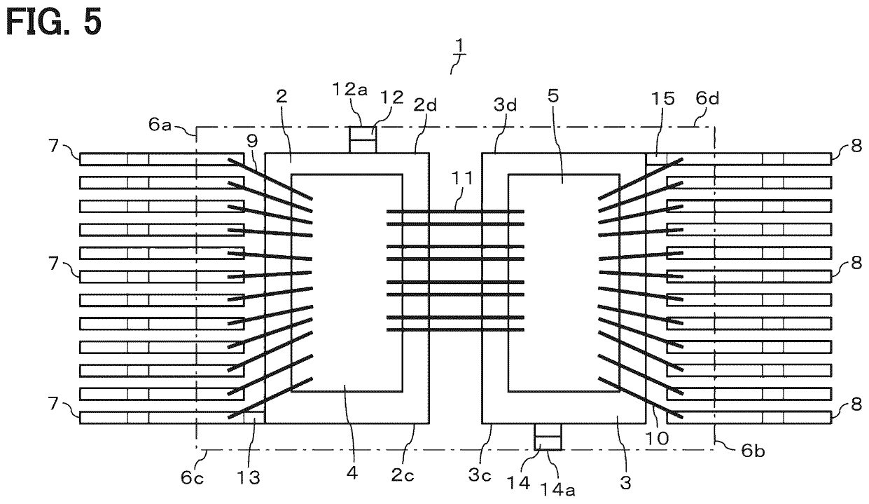

In the semiconductor device 1, a depressing process is performed. As a result, as shown in FIG. 4, the first island 2 and the second island 3 are staggered from the inner lead of the lead 7, 8 in a height direction. Specifically, in the semiconductor device 1, the first island 2 and the second island 3 are located at the lower side of the inner lead. However, in this case, as shown in FIGS. 1 and 5, the position of the first exposed portion 12a of the first extension portion 12 in the Z direction, i.e., the height position, is the same as the height position of the lead 7, 8 exposed to the outside of the package 6.

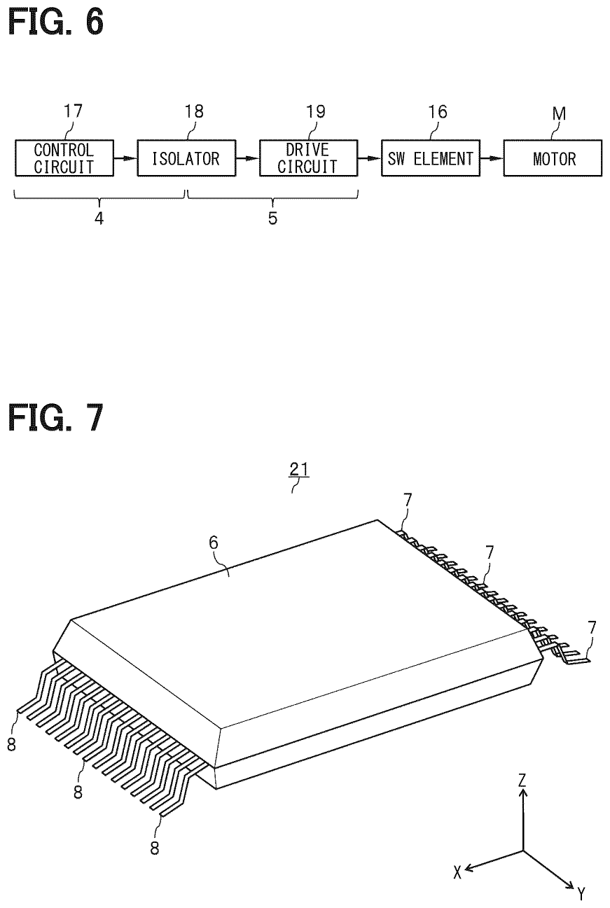

As shown in FIG. 6, the first semiconductor chip 4 and the second semiconductor chip 5 are implemented with various circuits for driving a switching element 16 of a three-phase inverter circuit for driving a motor M mounted on a vehicle. Specifically, the first semiconductor chip 4 and the second semiconductor chip 5 include a control circuit 17, an isolator 18, and a drive circuit 19. In FIG. 6, the switching element is abbreviated to SW element. The control circuit 17 outputs a drive command signal that commands the driving of the switching element 16.

The isolator 18 is an example of an insulating element, and is formed, for example, by a capacitive coupler. The drive circuit 19 drives the switching element 16 based on a drive command signal provided from the control circuit 17 via the isolator 18. Although FIG. 3 illustrates only one switching element 16, one isolator 18, and one drive circuit 19, in reality, there are six switching elements 16 and a corresponding number of isolators 18 and drive circuits 19.

In this case, the operating voltage of the control circuit 17 is a relatively low, for example, 12V, and the operating voltage of the drive circuit 19 is a relatively high, for example, 650V. The control circuit 17 and a part of the isolator 18 are mounted on the first semiconductor chip 4, and a part of the isolator 18 and the drive circuit 19 are mounted on the second semiconductor chip 5. According to the above configuration, in the semiconductor device 1, the first semiconductor chip 4 is on the low voltage side and the second semiconductor chip 5 is on the high voltage side, and the low voltage side and the high voltage side are insulated from each other by the isolator 18.

According to the present embodiment, the following effects are obtained. In the semiconductor device 1 of this embodiment, a suspension structure is adopted in which the first island 2 is supported on the package 6 by the first extension portion 12 and the first terminal connector 13, and the second island 3 is supported on the package 6 by the second extension portion 14 and the second terminal connector 15. With this configuration, of the multiple leads 7, 8 arranged on each of the first side 6a and the second side 6b, the leads 7h, 8a arranged at the both ends no longer need to be used to suspend the first island 2 and the second island 3, and can therefore be assigned as functional pins.

In this case, the first extension portion 12 and the second extension portion 14 are exposed from the third side 6c and the fourth side 6d, respectively, which are different from the first side 6a and the second side 6b on which the leads 7 and 8 are arranged, among the four sides of the package 6. Therefore, with the above configuration, the lead pitch, i.e., the distance between the terminals, does not become long as in a conventional suspension structure. As a result, the package size can be kept small. Therefore, according to this embodiment, it is possible to obtain the excellent effect of increasing the number of terminals that can be assigned as functional pins while keeping the package size small.

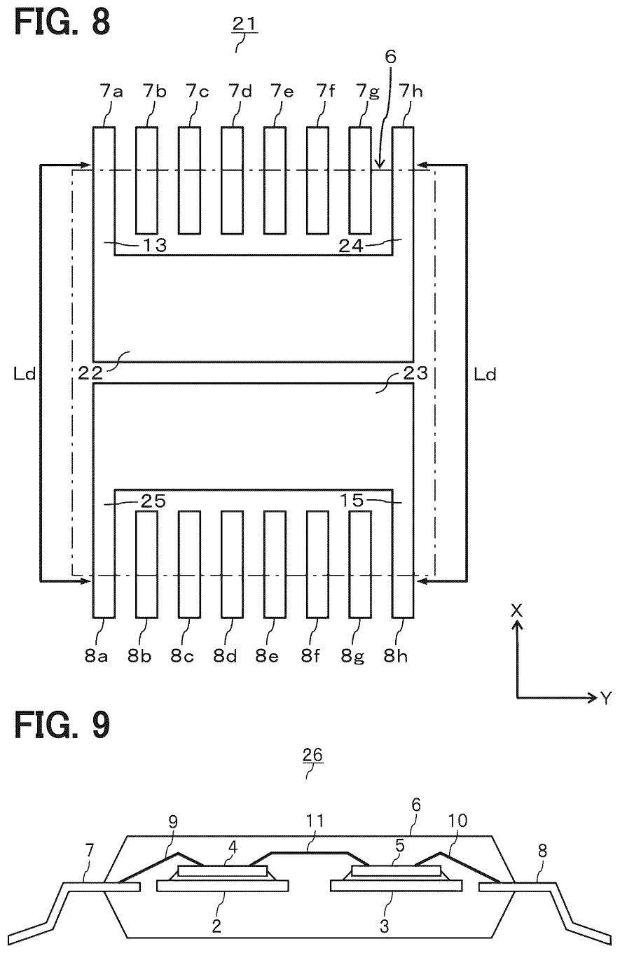

The effects obtained by this embodiment become even clearer when compared with a first comparative example, which is a semiconductor device employing a typical suspension structure in which an island is suspended by outer leads at both ends. As shown in FIGS. 7 and 8, a semiconductor device 21 of the first comparative example differs from the semiconductor device 1, and has a first island 22 and a second island 23 instead of the first island 2 and the second island 3.

The first island 22 differs from the first island 2, and includes a terminal connector 24 instead of the extension portion 12. The terminal connector 24 is connected to the lead 7h. As a result, the first island 22 is supported by the package 6 via the terminal connectors 13, 24. The second island 23 is different from the second island 3, and includes a terminal connector 25 instead of the extension portion 14. The terminal connector 25 is connected to the lead 8a. As a result, the second island 23 is supported by the package 6 through the terminal connectors 15, 25.

In the semiconductor device 21 of the first comparative example, all of the leads at the four corners, i.e., the leads 7a, 7h, 8a, and 8h, are fixed to the ground potential, which is the same potential as the island. In contrast, in the semiconductor device 1 of this embodiment, two of the leads at the four corners, i.e., the leads 7a and 8h, are fixed to the ground potential, but the remaining two leads, i.e., the leads 7h and 8a, can be assigned functional pins. That is, according to this embodiment, the number of terminals that can be assigned as functional pins can be increased by two, compared to the first comparative example.

In the semiconductor device 1, 21, depending on the size of the chip mounted thereon, the creepage distance required for insulation may be limited by the chip size. In such a case, in the semiconductor device 21 of the first comparative example, it is necessary to ensure a creepage distance Ld that is greater than or equal to the originally required distance. In contrast, the creepage distance in the semiconductor device 1 of this embodiment may be set to a distance equal to or greater than a specified distance that is specified based on the operating voltage of the circuit and the CTI value of the resin that constitutes the package 6. Therefore, in the semiconductor device 1 of this embodiment, the layout of the extension portion 12, 14 is determined so that the first exposed portion 12a and the second exposed portion 14a are located at positions where each of the creepage distances La, Lb, Lc is equal to or greater than the specified distance. Thus, it is possible to efficiently and reliably ensure the creepage distances required for insulation, compared to the semiconductor device 21 of the first comparative example.

In this embodiment, the first extension portion 12 extends so as to be exposed from the fourth side 6d at a position closer to the leads 7 than the center position of the side 2d in the X direction. The second extension portion 14 extends so as to be exposed from the third side 6c at a position closer to the leads 8 than the center position of the side 3c in the X direction. According to this configuration, it is possible to ensure the long creepage distance La, Lb. Therefore, the configuration of this embodiment is suitable for cases where a long creepage distance is required.

In this embodiment, the first terminal connector 13 is connected to the lead 7a located the farthest from the first extension portion 12, among the multiple leads 7 arranged on the first side 6a. The second terminal connector 15 is connected to the lead 8h located the farthest from the second extension portion 14, among the multiple leads 8 arranged on the second side 6b. With this configuration, it is possible to improve the balance for supporting the first island 2 by the first extension portion 12 and the first terminal connector 13 and for supporting the second island 3 by the second extension portion 14 and the second terminal connector 15, thereby improving the stability of the suspension.

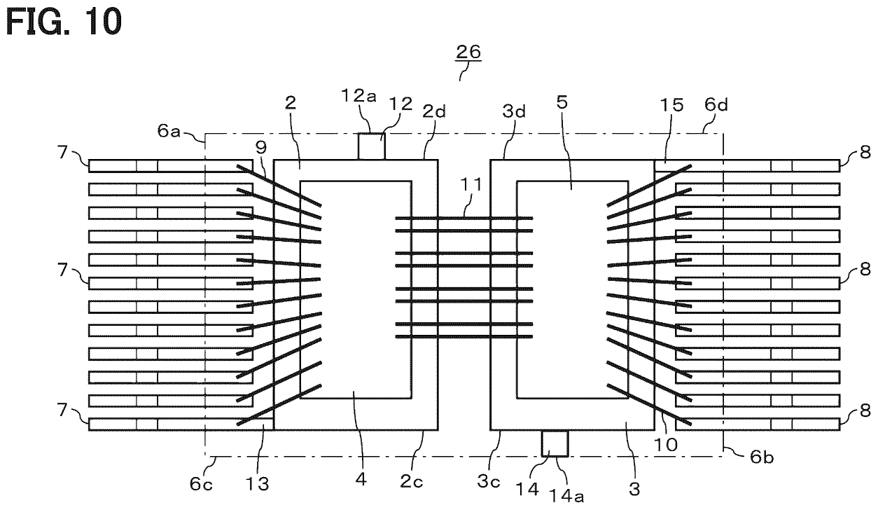

In this embodiment, the semiconductor device 1 has a depressed configuration. This provides the following advantages over a semiconductor device 26 of the second comparative example having no depression as shown in FIGS. 9 and 10. That is, as shown in FIG. 9, in the semiconductor device 26 of the second comparative example, the wire 9, 10 is more likely to be subjected to stress at a portion connected to the lead 7, 8, to be the second bonding in the wire bonding. Therefore, in the second comparative example, there is a high possibility that the wire 9, 10 will be broken due to crack or the like.

In contrast, as shown in FIG. 4, in this embodiment, the stress applied to the wire portion of the wire 9, 10 connected to the lead 7, 8, to be the second bonding in the wire bonding, is reduced compared to the second comparative example. Therefore, according to this embodiment, the possibility of breakage in the wire 9, 10 due to crack or the like can be reduced, compared to the second comparative example having a configuration without depression.

The suspension structure for supporting the first island 2 and the second island 3 on the package 6 is not limited to the structure described in the above embodiment, and can be modified, for example, as follows.

### (First Modification)

The first extension portion 12 may extend from the side 2d of the first island 2 so as to be exposed at the fourth side 6d at a position farther from the leads 7 arranged on the first side 6a of the package 6 with respect to the center of the side 2d in the X direction. The second extension portion 14 may extend from the side 3c of the second island 3 so as to be exposed at the third side 6c at a position farther from the leads 8 arranged on the second side 6b of the package 6 with respect to the center of the side 3c in the X direction. With this configuration, the balance is improved when suspending the islands 2, 3, to improve the suspension stability.

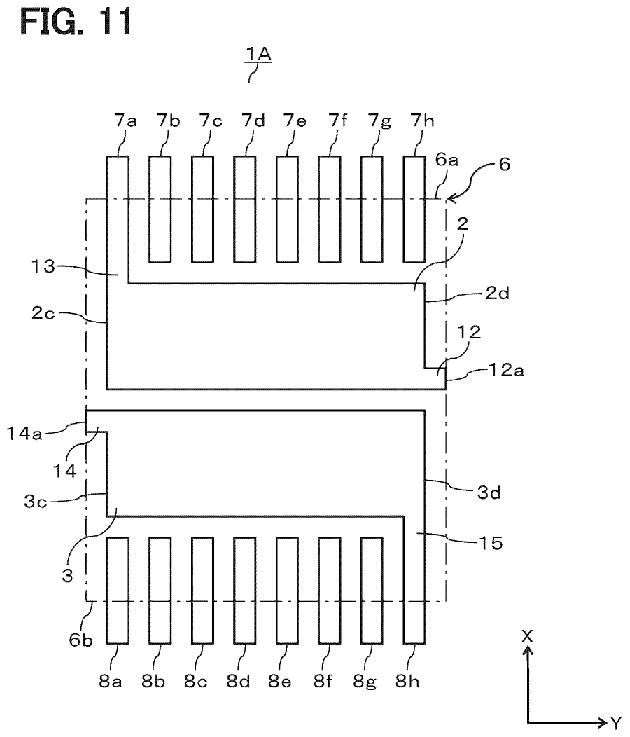

In order to maximize this effect, as shown in FIG. 11, in a semiconductor device 1A of a first modification, the first extension portion 12 extends so as to be exposed at the fourth side 6d at a position farthest from the leads 7 arranged on the first side 6a of the package 6. The second extension portion 14 extends so as to be exposed at the third side 6c at a position farthest from the leads 8 arranged on the second side 6b of the package 6. According to the semiconductor device 1A of the first modification, the effect of increasing the suspension stability can be maximized. Therefore, the first modification is more suitable for cases where a short creepage distance is acceptable.

### (Second Modification)

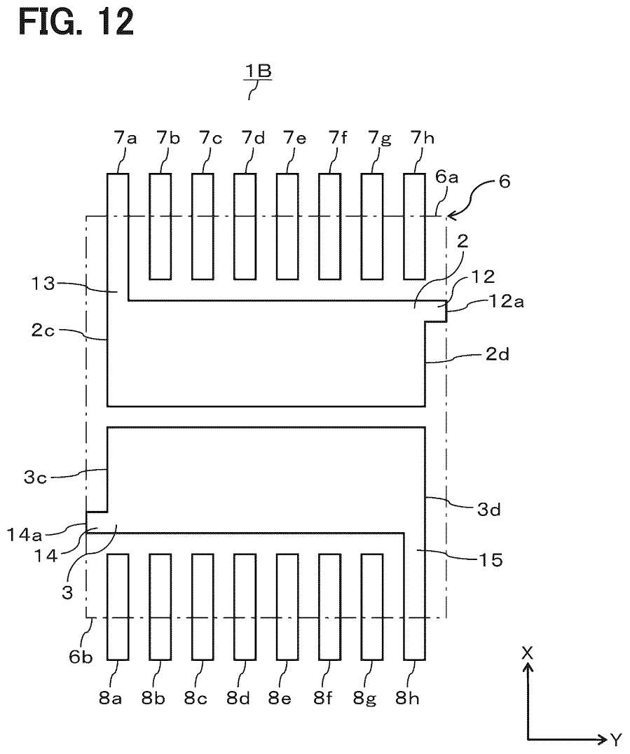

As shown in FIG. 12, a semiconductor device 1B of the second modification is different from the semiconductor device 1 in the arrangement of the first extension portion 12 and the second extension portion 14. In the semiconductor device 1B of the second modification, the first extension portion 12 extends so as to be exposed at the fourth side 6d at a position closest to the leads 7 arranged on the first side 6a of the package 6.

The second extension portion 14 extends so as to be exposed at the third side 6c at a position closest to the leads 8 arranged on the second side 6b of the package 6. According to the semiconductor device 1B of the second modification, it is possible to ensure a longer creepage distance, compared to the semiconductor device 1. Therefore, the second modification is more suitable when a long creepage distance is required.

### (Third Modification)

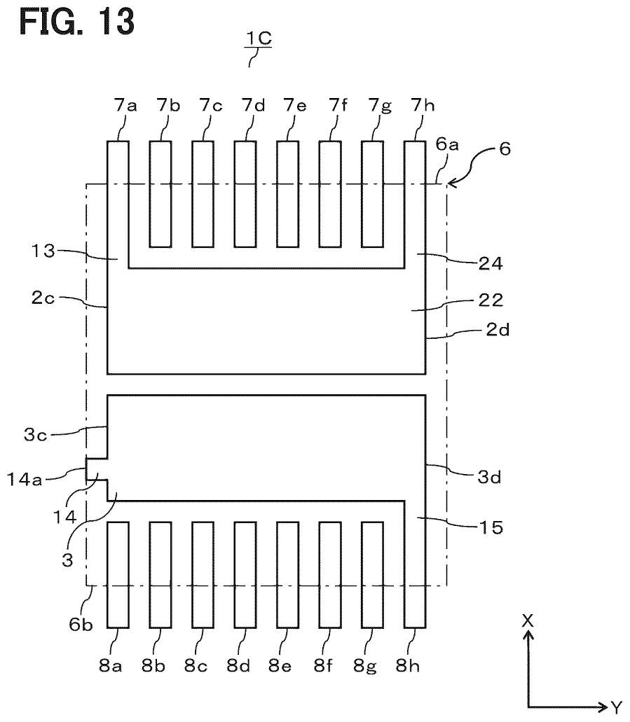

In the semiconductor device 1, the first island 2 has the extension portion 12, and is supported by the package 6 through the extension portion 12. The second island 3 has the extension portion 14, and is supported by the package 6 through the extension portion 14. However, obly one of the first island 2 and the second island 3 may have an extension portion and be supported by the package 6 through the extension portion. For example, a configuration like a semiconductor device 1C according to a third modification shown in FIG. 13 can be adopted.

As shown in FIG. 13, a semiconductor device 1C of the third modification is different from the semiconductor device 1 in that, instead of the first island 2, a first island 22 similar to the semiconductor device 21 of the comparative example is provided. That is, in the semiconductor device 1C, the second island 3 is supported by the package 6 via the extension portion 14 and the second terminal connector 15, while the first island 22 is supported by the package via the terminal connectors 13 and 24.

According to the third modification, three leads 7a, 7h, and 8h of the four corner leads are fixed to the ground potential, but the remaining lead 8a can be assigned a functional pin. That is, according to the third modification, the number of terminals that can be assigned as functional pins can be increased by one, compared to the comparative example. Therefore, the third modification also has the effect of increasing the number of terminals that can be assigned as functional pins.

### (Fourth Modification)

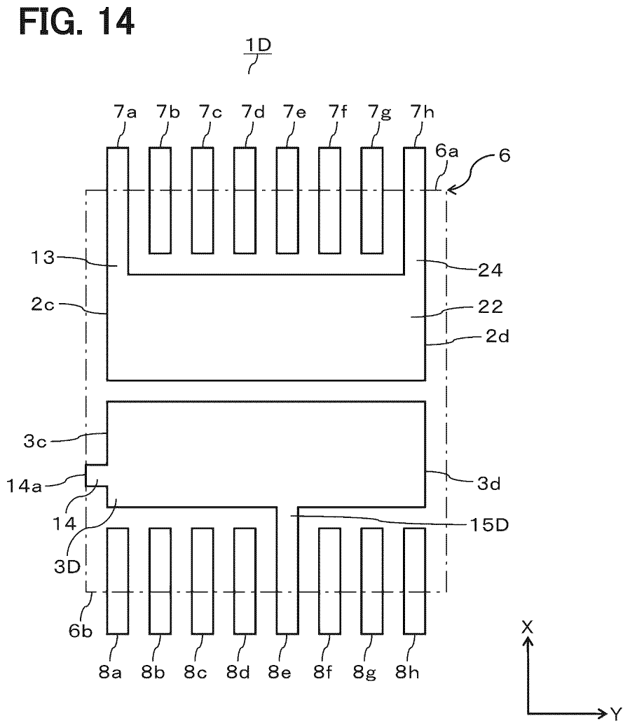

In the semiconductor device 1, the terminal connector 13, 15 is connected to the lead located furthest from the extension portion 12, 14, among the multiple leads 7, 8 arranged on the side 6a, 6b of the package 6. However, the terminal connector 13, 15 may be connected to any of the multiple leads 7, 8 arranged on the side 6a, 6b of the package 6. For example, a configuration like a semiconductor device 1D of a fourth modification shown in FIG. 14 can be adopted.

As shown in FIG. 14, the semiconductor device 1D of the fourth modification is different from the semiconductor device 1C of the third modification in that a second island 3D is provided instead of the second island 3. The second island 3D is different from the second island 3, and includes a second terminal connector 15D instead of the second terminal connector 15. The second terminal connector 15D is connected to one of the multiple leads 8 arranged on the second side 6b of the package 6, specifically to the lead 8e.

As a result, the second island 3D is supported on the package 6 by the second extension portion 14 and the second terminal connector 15D. According to the fourth modification, the support balance of the second island 3D is slightly worse than in the third modification, but apart from that, it is possible to obtain substantially the same effects.

### (Fifth Modification)

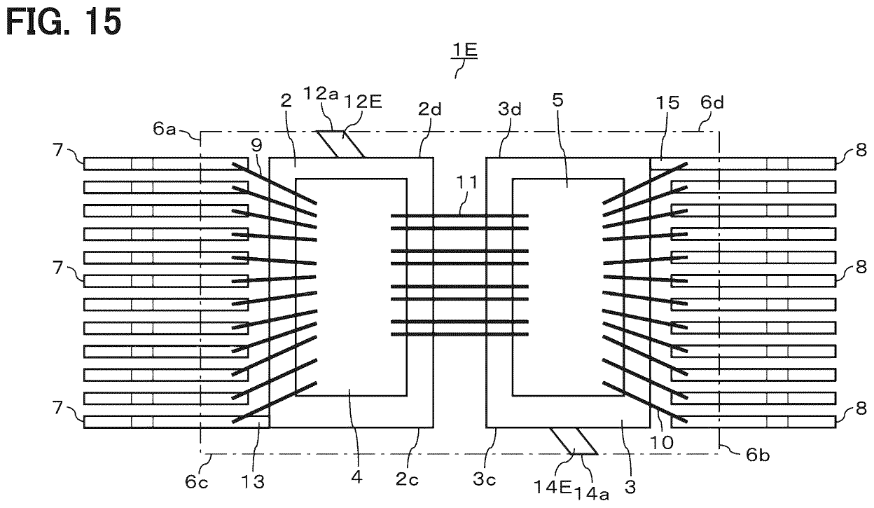

In the semiconductor device 1, the extension portion 12 extends straight from the first island 2 toward the fourth side 6d, and the extension portion 14 extends straight from the second island 3 toward the third side 6c. That is, in the semiconductor device 1, the extension portion 12, 14 is shaped to extend straight along the Y direction, but may be shaped to extend obliquely along a direction intersecting the Y direction or/and the X direction. For example, a configuration like a semiconductor device 1E according to a fifth modification shown in FIG. 15 can be adopted.

As shown in FIG. 15, the semiconductor device 1E of the fifth modification differs from the semiconductor device 1, and has a first extension portion 12E and a second extension portion 14E instead of the first extension portion 12 and the second extension portion 14. The first extension portion 12E extends obliquely from the first island 2, and more specifically, extends obliquely so as to be exposed at the fourth side 6d at a position closer to the multiple leads 7 relative to the center of the side 2d in the X direction.

The second extension portion 14E extends obliquely from the second island 3, and more specifically, extends obliquely so as to be exposed at the third side 6c at a position closer to the multiple leads 8 relative to the center of the side 3c in the X direction. According to the semiconductor device 1E of the fifth modification, it is possible to ensure a longer creepage distance for the semiconductor device 1. Therefore, the fifth modification is more suitable when a long creepage distance is required.

### (Sixth Modification)

In the semiconductor device 1, the extension portion 12 is shaped to extend from a part of the side 2d of the first island 2, and the extension portion 14 is shaped to extend from a part of the side 3c of the second island 3. In the semiconductor device 1, the length dimension of the extension portion 12 in the X direction is much shorter than the length dimension of the side 2d, and the length dimension of the extension portion 14 in the X direction is much shorter than the length dimension of the side 3c.

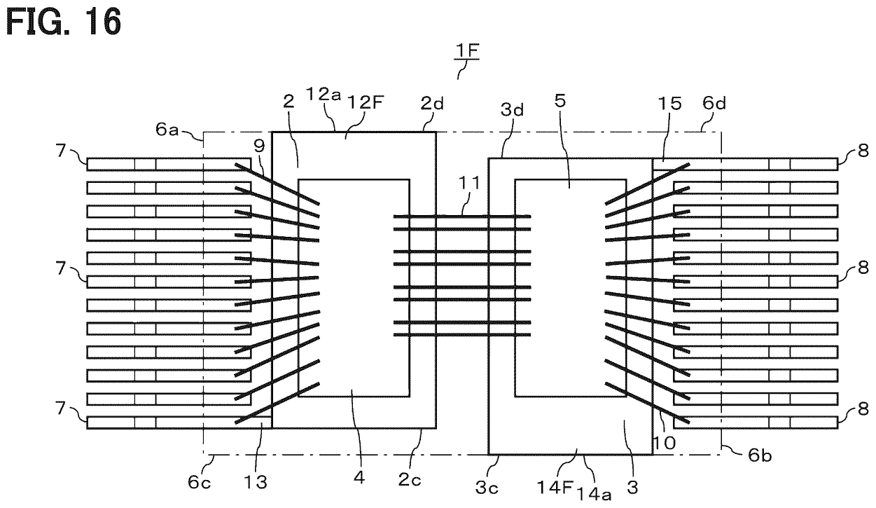

However, the length dimension of the extension portion 12, 14 in the X direction is not limited to this and can be changed as appropriate. For example, a configuration such as a semiconductor device 1F of a sixth modification shown in FIG. 16 can be adopted. As shown in FIG. 16, the semiconductor device 1F of the sixth modification differs from the semiconductor device 1, and has a first extension portion 12F and a second extension portion 14F instead of the first extension portion 12 and the second extension portion 14.

The first extension portion 12F is shaped to extend from the entire side 2d of the first island 2, and the length of the first extension portion 12F in the X direction is the same as the length of the side 2d. The second extension portion 14 is shaped to extend from the entire side 3c of the second island 3, and the length in the X direction is the same as the length of the side 3c. According to the semiconductor device 1F of the sixth modification, the first island 2 and the second island 3 of the semiconductor device 1 can be supported more firmly with respect to the package 6, thereby further improving the stability of the suspension.

### (Seventh Modification)

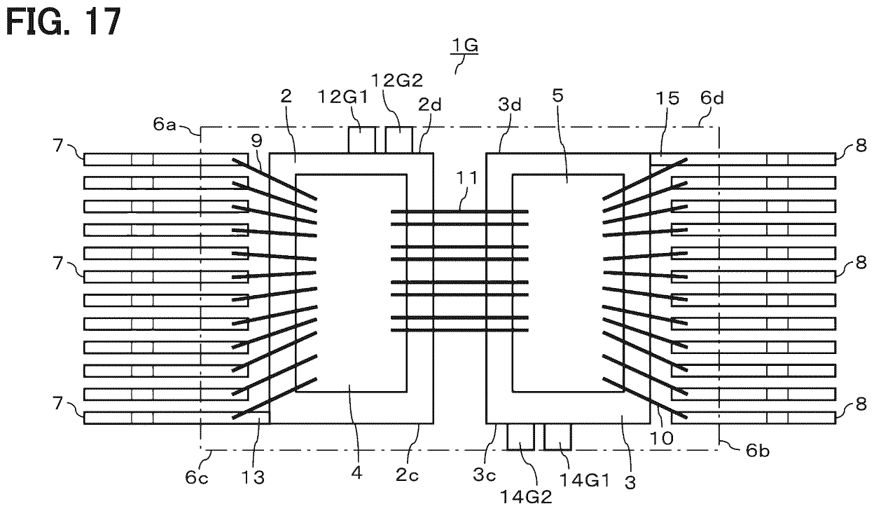

In the semiconductor device 1, each of the first island 2 and the second island 3 has one extension portion, but one or both of the first island 2 and the second island 3 may have multiple extension portions. For example, a configuration like a semiconductor device 1G according to a seventh modification shown in FIG. 17 can be adopted.

As shown in FIG. 17, the semiconductor device 1G of the seventh modification differs from the semiconductor device 1, and has first extension portions 12G1, 12G2 and second extension portions 14G1, 14G2 instead of the first extension portion 12 and the second extension portion 14. Similar to the extension portion 12, the first extension portion 12G1, 12G2 has a shape extending so as to be exposed at the fourth side 6d. Similar to the extension portion 14, the second extension portion 14G1, 14G2 extends so as to be exposed at the third side 6c.

In this way, according to the semiconductor device 1G of the seventh modification, since each of the first island 2 and the second island 3 has multiple extension portions, it is possible for the first island 2 and the second island 3 to be more firmly supported relative to the package 6 of the semiconductor device 1, thereby further increasing the stability of the suspension.

### (Eighth Modification)

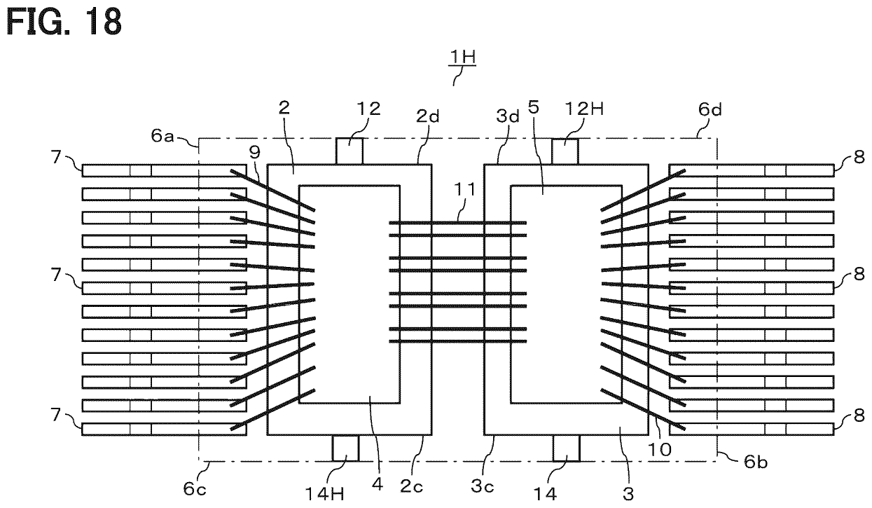

In the semiconductor device 1, the first island 2 and the second island 3 are both supported on the package 6 by the extension portion and the terminal connector. However, one or both of the first island 2 and the second island 3 may be supported on the package 6 only by the extension portion. For example, a configuration such as a semiconductor device 1H according to an eighth modification shown in FIG. 18 can be adopted.

As shown in FIG. 18, a semiconductor device 1H of the eighth modification is different from the semiconductor device 1, and includes a first island 2 and a second island 3. The first island 2 includes an extension portion 14H instead of the terminal connector 13. The extension portion 14H extends so as to be exposed from the third side 6c, and is formed integrally with the first island 2, similar to the extension portion 12. In this case, the extension portion 14H will be referred to as a first extension portion. The first island 2 is supported on the package 6 by the two extension portions 12 and 14H.

The second island 3 includes an extension portion 12H instead of the terminal connector 15. The extension portion 12H extends so as to be exposed at the fourth side 6d, and is formed integrally with the second island 3, similar to the extension portion 14. In this case, the extension portion 12H will be referred to as a second extension portion. The second island 3 is supported on the package 6 by the two extension portions 14 and 12H.

In this way, in the semiconductor device 1H of the eighth modification, of the multiple leads 7 arranged on the first side 6a and the multiple leads 8 arranged on the second side 6b, there is no need to use all of the leads 7a, 7h, 8a, 8h arranged at the both ends to suspend the first island 2 and the second island 3. Therefore, according to the semiconductor device 1H of the eighth modification, it is possible to assign functional pins to all of the leads at the four corners, and the number of terminals that can be assigned as functional pins can be increased by four, compared to the first comparative example.

### Second Embodiment

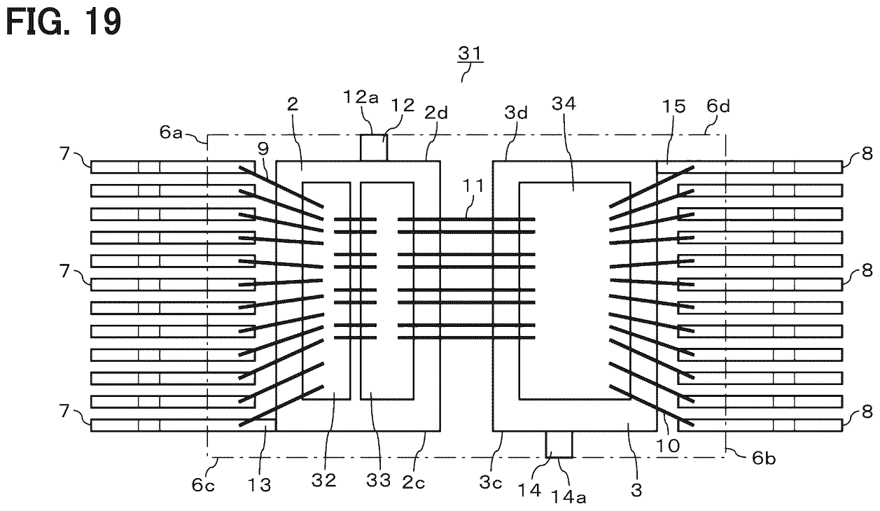

Hereinafter, a second embodiment will be described with reference to the drawings. As shown in FIG. 19, the semiconductor device 31 of this embodiment differs from the semiconductor device 1 of the first embodiment, and the semiconductor chips mounted on the first island 2 and the second island 3 are configured as three chips. That is, two semiconductor chips 32 and 33 are mounted on the first island 2, and one semiconductor chip 34 is mounted on the second island 3.

In this case, the semiconductor chips 32 and 33 are referred to as first semiconductor chip 32, 33, and the semiconductor chip 34 is referred to as second semiconductor chip 34. The first semiconductor chip 32, 33 and the second semiconductor chip 34 are all made of a semiconductor such as silicon, and have a rectangular plate shape. The first semiconductor chip 32 is a communication chip, and is provided with the control circuit 17 and the like described in the first embodiment. The second semiconductor chip 34 is an output chip, and is provided with the drive circuit 19 and the like described in the first embodiment.

The first semiconductor chip 33 is a coupler chip, and is provided with an insulating element for insulating between the circuits mounted on the first semiconductor chip 32 and the second semiconductor chip 34. In this case, the insulating element may be, for example, a magnetic coupler. According to the above configuration, in the semiconductor device 31, the first semiconductor chip 32 is a low voltage side and the second semiconductor chip 34 is a high voltage side. The low voltage side and the high voltage side are insulated from each other by an insulating element provided in the first semiconductor chip 33.

Even if the semiconductor chips mounted on the first island 2 and the second island 3 have a three-chip configuration as in the semiconductor device 31 of the present embodiment, a suspension structure similar to that of the first embodiment in which the semiconductor chips mounted on the first island 2 and the second island 3 have a two-chip configuration can be adopted. Therefore, this embodiment also has the same effect as the first embodiment, that is, the excellent effect of being able to increase the number of terminals that can be assigned as functional pins while keeping the package size small.

### Other Embodiment

The present disclosure is not limited to the embodiments that have been described above and illustrated in the drawings, but can arbitrarily be modified, combined, or expanded without departing from the spirit of the present disclosure. The numerical values and the like shown in the embodiments described above are examples, and are not limited to those examples.

The present disclosure is not limited to the SOP type semiconductor device, but can be applied to a semiconductor device in general, such as SON type semiconductor device, that includes a package having four sides in a plan view, and in which terminals are arranged on two of the four sides opposite to each other. The SON is an abbreviation for Small Outline Non-leaded package. The suspension structure of the first island and the suspension structure of the second island do not necessarily have to be the same structure, and different suspension structures may be adopted.

Although the present disclosure has been described in accordance with the examples, it is to be understood that the disclosure is not limited to such examples or structures. The present disclosure encompasses various modifications and variations within the scope of equivalents. In addition, while the various elements are shown in various combinations and configurations, which are exemplary, other combinations and configurations, including more, less or only a single element, are also within the spirit and scope of the present disclosure.

What is claimed is:

1. A semiconductor device comprising:
a package having a first side, a second side, a third side and a fourth side in a plan view;
a plurality of terminals arranged along each of the first side and the second side of the package opposing to each other;
a first island having four sides in a plan view, one of the four sides of the first island opposing the first side of the package;
a second island, separated from the first island, having four sides in a plan view, one of the four sides of the second island opposing the second side of the package;
at least one first semiconductor chip mounted on the first island;
at least one second semiconductor chip mounted on the second island;
an insulating element provided on one or both of the first semiconductor chip and the second semiconductor chip;
a first wire electrically connecting the first semiconductor chip to the plurality of terminals arranged on the first side of the package;
a second wire electrically connecting the second semiconductor chip to the plurality of terminals arranged on the second side of the package; and
a third wire electrically connecting the first semiconductor chip and the second semiconductor chip, wherein
the first island has: a first extension portion extending to be exposed from one of the third side and the fourth side of the package; and a first terminal connector connected to a terminal, positioned farthest from the first extension portion, of the plurality of terminals arranged on the first side,
the first island is supported by the package through the first extension portion and the first terminal connector,
the second island has: a second extension portion extending to be exposed from the other of the third side and the fourth side; and a second terminal connector connected to a terminal, positioned farthest from the second extension portion, of the plurality of terminals arranged on the second side, and
the second island is supported by the package through the second extension portion and the second terminal connector.

2. The semiconductor device according to claim 1, wherein
the first extension portion is located at a position farther from the plurality of terminals arranged on the first side than a center position of the one of the third side and the fourth side is, and
the second extension portion is located at at a position farther from the plurality of terminals arranged on the second side than a center position of the other of the third side and the fourth side is.

3. The semiconductor device according to claim 1, wherein
the first extension portion is located at a position between the plurality of terminals arranged on the first side and a center position of the one of the third side and the fourth side, and
the second extension portion is located at at a position between the plurality of terminals arranged on the second side and a center position of the other of the third side and the fourth side.

4. The semiconductor device according to claim 1, wherein a creepage distance between a first exposed portion exposed to outside of the package and electrically connected to the first island and a second exposed portion exposed to outside of the package and electrically connected to the second island is equal to or greater than a predetermined specified distance for insulation.

5. The semiconductor device according to claim 1, wherein
the first extension portion is one of a plurality of first extension portions, and
the second extension portion is one of a plurality of second extension portions.
